(19) United States
(12) Patent Application Publication
(10) Pub. No.: US 2007/0144774 A1
(43) Pub. Date: Jun. 28, 2007

(54) Circuit board assembly with fine electrically connecting structure

(76) Inventor: Shih-Ping Hsu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/487,868

(22) Filed: Jul. 17, 2006

(30) Foreign Application Priority Data
Dec. 27, 2005 (TW) 094146635

(51) Int. Cl. H05K 1/11; H01R 12/04

(52) U.S. Cl. 174/262

(57) ABSTRACT

A circuit board assembly with a fine electrically connecting structure is proposed, which includes at least a first circuit layer and at least a dielectric layer formed on surfaces of a circuit board and the first circuit layer. At least one opening is formed penetrating through the dielectric layer for exposing the first circuit layer. Also, at least a fine electrically connecting structure which is electrically connected to the first circuit layer is formed in the opening of the dielectric layer. The fine electrically connecting structure is made of a conductive composite material with a net-like interconnection configuration. At least a second circuit layer which includes at least a circuit and an electrical pad is formed on surfaces of the dielectric layer and the fine electrically connecting structure. By such arrangement, the first circuit layer can be electrically connected to the second circuit layer by the means of the fine electrically connecting structure, so as to achieve electrical connection of fine openings.

### CROSS-REFERENCE TO RELATED APPLICATION

This application claims benefit under 35 USC 119 to Taiwan Application No. 094146635, filed Dec. 27, 2005.

### FIELD OF THE INVENTION

The present invention relates to a circuit board assembly with fine electrically connecting structure, and more particularly, to a circuit board having fine openings with fine electrically connecting structures for electrically connecting interlayer circuits.

### BACKGROUND OF THE INVENTION

Along with the blooming development of various portable products in the fields of communication, networking and computing, packages such as ball grid array (BGA), flip chip, chip size package (CSP) and multi chip module (MCM) which are characterized with a miniaturized integrated circuit (IC) area, a high density and multiple leads have become the mainstream of the packaging market. Highly effective chips such as a microprocessor, a chip set, a drawing chip and an application-specific integrated circuit (ASIC) are usually combined with the foregoing package to achieve an operating function with a higher speed. However, the integrated circuit (IC) packaging substrate formed with traces is usually limited by its fabrication method. In other words, the limitations in the functions of the packaging substrate such as transmission signal of the chip, an improved bandwidth and resistance control impede the development of a package with a large number of input/output (I/O) connections. Furthermore, the fabrication cost of the substrate is about 20%˜50% of the overall packaging cost. Therefore, as the line space of the integrated circuit fabrication of a semiconductor chip has already reduced to 0.09 μm and the packaging size is also continuously miniaturized to the approximate size of the chip (about 1.2 times of the chip size), research directed to the integrated circuit and other related electronic industry has focused on ways to propose a semiconductor packaging substrate with a fine circuit, a high density and a small opening.

Accordingly, in order to meet the miniaturization requirement of a semiconductor packaging substrate, a conductive via is usually employed to electrically connect different circuit layers of a circuit board. FIG. 1 is a cross-sectional view of a conductive via structure of a prior-art circuit board. Referring to FIG. 1, a circuit board 10 comprises a first circuit layer 11, a second circuit layer 13 and a dielectric layer 12 formed between the first circuit layer 11 and the second circuit layer 13. The dielectric layer 12 is formed with at least one opening 120 for exposing an electrical pad 110 formed on the first circuit layer 11. Further, the second circuit layer 13 is electrically connected to the electrical pad 110 of the first circuit layer 11 by the means of a conductive via 131 formed in the opening 120 of the dielectric layer 12, such that the first circuit layer 11 is electrically connected to the second circuit layer 13 by the means of the conductive via 131. Moreover, the first circuit layer 11, the second circuit layer 13 and the conductive via 131 are made of materials such as copper metals.

During the fabrication method of the prior-art semiconductor packaging substrate, the conductive via 131 is formed in the opening 120 of the dielectric layer 12 by electroplating. However, in order to meet the miniaturization requirement of the semiconductor package, when a finer conductive via which has a size smaller than 30 μm is to be fabricated by electroplating, it would be problematical to control the quality of the conductive via due to the difficulties in electroplating techniques. Therefore, the electrical connection between circuit layers may be adversely influenced, resulting in an unreliable product.

Therefore, the problem to be solved here is to provide a fine electrically connecting structure, by which the quality of the electrical connection between different circuit layers of a circuit board remains to be improved.

### SUMMARY OF THE INVENTION

A primary objective of the present invention is to provide a circuit board assembly with a fine electrically connecting structure, by which the quality of electrical connection of the circuit board can be improved.

Another objective of the present invention is to provide a circuit board with a fine electrically connecting structure, by which the binding intensity between a circuit layer and a dielectric layer can be reinforced.

A further objective of the present invention is to provide a circuit board with a fine electrically connecting structure which can be applied to a circuit board with fine circuit fabrication.

In accordance with the above and other objectives, the present invention proposes a circuit board with a fine electrically connecting structure, comprising a circuit board having at least a first circuit layer; at least a dielectric layer formed on surfaces of the circuit board and the first circuit layer, wherein at least one opening is formed penetrating through the dielectric layer for exposing the first circuit layer; at least a fine electrically connecting structure formed in the opening of the dielectric layer and electrically connected to the first circuit layer; and at least a second circuit layer formed on surfaces of the dielectric layer and the fine electrically connecting structure, such that the first circuit layer is electrically connected to the second circuit layer by the means of the fine electrically connecting structure.

The first circuit layer and the second circuit layer are made by copper metals, and the fine electrically connecting structure is a conductive composite material with a net-liking bonding configuration. Thus, the first circuit layer is electrically connected to the second circuit layer when copper ions are migrated to the fine electrically connecting structure made of the conductive composite material during electrical induction.

The conductive composite material which is an organic composite material characterized with electrical conductivity is selected from the group consisting of copper (Cu), silver (Ag), graphite, gold (Au), aluminium (Al), magnesium (Mg), iron (Fe) and zinc (Zn).

In the present invention, the fine electrically connecting structure is a conductive composite material with a net-like bonding configuration, such as an organic composite material characterized with electrical conductivity. Thus, the copper ions in the first and the second circuit layers can migrate to the conductive composite material. As no obvious connecting interfaces exist between the first and the second circuit layers, an interface problem does not occur between the fine electrically connecting structure and the circuit layers, so as to result in a high binding intensity. Furthermore, the performance of electrical connection using the fine electrically connecting structure proposed in the present invention does not require a large dimensioned opening in the dielectric layer. Therefore, the present invention can be applied to a circuit board with fine circuit fabrication while improving the quality of electrical connection of the circuit board and resulting in highly reliable electrical connection.

The fine electrically connecting structure proposed in the present invention is an organic composite material with a net-like bonding configuration which is characterized with electrical conductivity. Thus, the binding intensity between the fine electrically connecting structure and the dielectric layer can be reinforced by the means of the organic composite material. Moreover, the net-like bonding configuration is highly thermal-tolerated, by which the quality of the fine electrically connecting structure can be effectively controlled to prevent disconnection between circuit layers.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a conductive via structure of a prior-art circuit board;

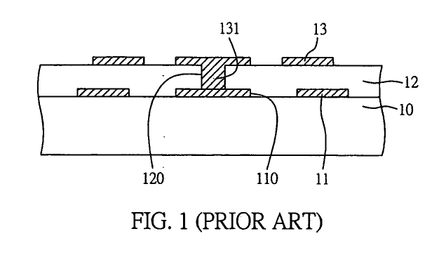

FIG. 2A to FIG. 2D are cross-sectional views of a circuit board with a fine electrically connecting structure according to the present invention; and

FIG. 2D′ is a cross-sectional view of a double layer circuit board with a fine electrically connecting structure according to the present invention.

### DETAILED DESCRIPTION OF THE EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

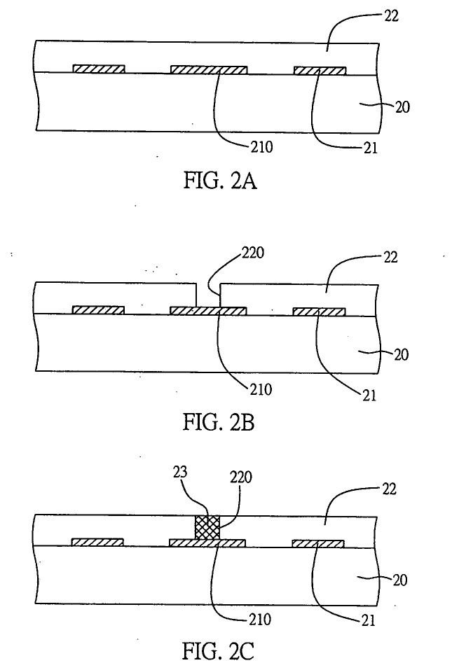

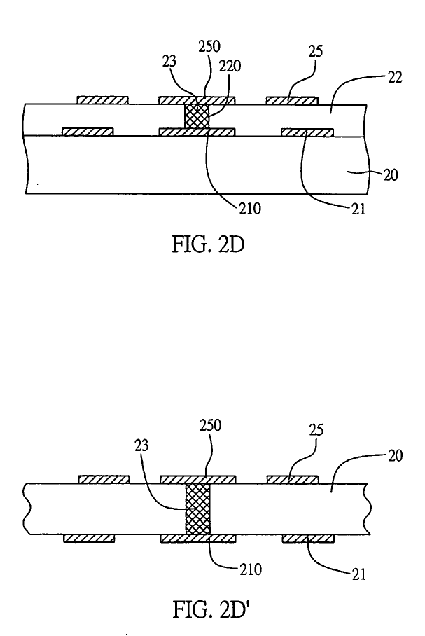

FIG. 2A to FIG. 2D are cross-sectional views of a circuit board with a fine electrically connecting structure according to the present invention, wherein circuit layers of a circuit board can be electrically connected. In the present embodiment, the fine electrically connecting structure is a conductive via.

Referring to FIG. 2A, a circuit board 20 formed with a first circuit layer 21 on a surface thereof is provided. The first circuit layer 21 is formed with at least one electrical pad 210. Further, a dielectric layer 22 is formed on surfaces of the circuit board 20 and the first circuit layer 21. The circuit board 20 can be a circuit board which has already completed with circuit patterning process. The first circuit layer 21 is made of copper metals and can be any circuit layer formed on the circuit board. Moreover, the dielectric layer 22 can be made of photosensitive or non-photosensitive organic resins, mixed epoxy resins and glass fibers selected from the group consisting of Ajinomoto build-up film (ABF), benzocyclo-buthene (BCB), liquid crystal polymer (LCP), poly-imide (PI), poly phenylene ether (PPE), poly tetrafluoro ethylene (PTFE), FR4, FR5, bismaleimide triazine (BT) and aramide.

Referring to FIG. 2B, the dielectric layer 22 is formed with an opening 220 at a position corresponding to the electrical pad 210 of the first circuit layer 21, such that the electrical pad 210 of the first circuit layer 21 can be exposed.

Referring to FIG. 2C, a fine electrically connecting structure 23 is formed in the opening 220 of the dielectric layer 22 and connected to the electrical pad 210 of the first circuit layer 21. The fine electrically connecting structure 23 is a conductive composite material with a net-like bonding configuration and can be selected from the group consisting of copper (Cu), silver (Ag), graphite, gold (Au), aluminium (Al), magnesium (Mg), iron (Fe) and zinc (Zn).

Referring to FIG. 2D, a second circuit layer 25 is formed on a surface of the dielectric layer 22 by circuit patterning process. Also, the second circuit layer 25 is formed with an electrical pad 250 at a position corresponding to the fine electrically connecting structure 23, such that the first circuit layer 21 is electrically connected to the second circuit layer 25 by the means of the fine electrically connecting structure 23. During the circuit fabrication, copper ions in the first circuit layer 21 and the second circuit layer 25 are migrated to the net-like bonding configuration of the fine electrically connecting structure 23 by electrical induction, such that the first circuit layer 21 can be electrically connected to the second circuit layer 25.

Apart from the build-up structure of the circuit board shown in FIG. 2A to FIG. 2D, as shown in FIG. 2D′ the fine electrically connecting structure proposed in the present invention can also be applied to electrically connect circuit layers of a double layer circuit board which has been completed with circuit patterning process. In the present embodiment, the first circuit layer 21 and the second circuit layer 25 are respectively formed on an upper surface and a lower surface of the circuit board 20. The first and the second circuit layers 21 and 25 are formed with a plurality of corresponding electrical pads 210 and 250 which are electrically connected by the means of the fine electrically connecting structure 23. The fabrication method of the double layer circuit board is similar to the foregoing embodiment and is already known in the prior-art, and thus will not be further described in details.

In the present invention, the copper ions in the circuits are migrated to bind the conductive composite material, such that the copper metal can be formed on the net-like bonding configuration of the conductive composite material. As the foregoing copper migration is able to form a prior-art dendrite and can be easily understood by one skilled in the pertinent art, it will not be further described in details.

The structure fabricated using the foregoing method comprises a circuit board 20 having at least a first circuit layer 21 which is formed with at least an electrical pad 210; at least a dielectric layer 22 formed on a surface of the first circuit layer 21, wherein at least an opening 220 is formed penetrating through the dielectric layer 22 for exposing the electrical pad 210 of the first circuit layer 21; at least a fine electrically connecting structure 23 formed in the opening 220 of the dielectric layer 22 and electrically connected to the electrical pad 210 of the first circuit layer 21; and at least a second circuit layer 25 formed on surfaces of the dielectric layer 22 and the fine electrically connecting structure 23, such that the first circuit layer 21 is electrically connected to the second circuit layer 25 by the means of the fine electrically connecting structure 23.

The present invention also proposes electrical connection of a double layer circuit board 20 which has been completed with circuit patterning process. The double layer circuit board 20 which has been completed with circuit patterning process is respectively formed with a first circuit layer 21 and a second circuit layer 25 on an upper surface and a lower surface thereof. Also, the first and the second circuit layers 21 and 25 are formed with a plurality of corresponding electrical pads 210 and 250. Furthermore, a fine electrically connecting structure 23 which is made of a conductive composite material with a net-like bonding configuration is formed between the corresponding electrical pads 210 and 250, such that the first circuit layer 21 is electrically connected to the second circuit layer 25 by the means of the fine electrically connecting structure 23.

In the present invention, the fine electrically connecting structure 23 is a conductive composite material with a net-like bonding configuration, such as an organic composite material characterized with electrical conductivity. Thus, the copper ions in the first circuit layer 21 and the second circuit layer 25 can be migrated to the conductive composite material. As no obvious connecting interfaces exist between the first circuit layer 21 and the second circuit layer 25, an interface problem does not occur between the fine electrically connecting structure 23 and the circuit layers, so as to result in a high binding intensity. Furthermore, the fine electrically connecting structure with a net-like bonding configuration can be used to electrically connect the first circuit layer and the second circuit layer, so as to achieve electrical connection of fine conductive vias.

Moreover, the performance of electrical connection using the fine electrically connecting structure proposed in the present invention does not require a large dimensioned opening in the dielectric layer 22. Therefore, the present invention can be applied to a circuit board with fine circuit fabrication while improving the quality of electrical connection of the circuit board and resulting in highly reliable electrical connection.

The fine electrically connecting structure 23 proposed in the present invention is an organic composite material with a net-like bonding configuration which is characterized with electrical conductivity. Thus, the binding intensity between the fine electrically connecting structure and the dielectric layer can be reinforced by the means of the organic composite material. Moreover, as the net-like bonding configuration is highly thermal-tolerated, the quality of the fine electrically connecting structure 23 can be effectively controlled to prevent disconnection between circuit layers, so as to improve product yields.

The invention has been described using exemplary preferred embodiments. However, it is to be understood that the scope of the invention is not limited to the disclosed embodiments. On the contrary, it is intended to cover various modifications and similar arrangements; for example, the number and locations of capacitors can be flexibly arranged according to practical requirements. The scope of the claims, therefore, should be accorded the broadest interpretation so as to encompass all such modifications and similar arrangements.

What is claimed is:

1. A circuit board assembly with a fine electrically connecting structure, comprising:
a circuit board having at least a first circuit layer;
at least a dielectric layer formed on surfaces of the circuit board and the first circuit layer, wherein at least one opening is formed penetrating through the dielectric layer for exposing the first circuit layer;
at least a fine electrically connecting structure formed in the opening of the dielectric layer and electrically connected to the first circuit layer, wherein the fine electrically connecting structure is made of a conductive composite material with a net-like interconnecting configuration; and
at least a second circuit layer formed on surfaces of the dielectric layer and the fine electrically connecting structure, such that the first circuit layer is electrically connected to the second circuit layer by the means of the fine electrically connecting structure.

2. The circuit board assembly with a fine electrically connecting structure of claim 1, wherein the first circuit layer and the second circuit layer are respectively formed with at least an electrical pad.

3. The circuit board assembly with a fine electrically connecting structure of claim 2, wherein the fine electrically connecting structure serves to connect the electrical pad of the first circuit layer and the second circuit layer.

4. The circuit board assembly with a fine electrically connecting structure of claim 1, wherein the first circuit layer and the second circuit layer are made of copper metal.

5. The circuit board assembly with a fine electrically connecting structure of claim 1, wherein the fine electrically connecting structure, which is made of a conductive composite material, allows copper in the first circuit layer and the second circuit layer to be migrated thereto, so as to electrically connect the first circuit layer and the second circuit layer.

6. The circuit board assembly with a fine electrically connecting structure of claim 5, wherein the copper migration is induced by electricity.

7. The circuit board assembly with a fine electrically connecting structure of claim 5, wherein the conductive composite material is selected from the group consisting of copper (Cu), silver (Ag), graphite, gold (Au), aluminium (Al), magnesium (Mg), iron (Fe) and zinc (Zn).

8. The circuit board assembly with a fine electrically connecting structure of claim 1, wherein the dielectric layer is made of photosensitive or non-photosensitive organic resins, mixed epoxy resins and glass fibers selected from the group consisting of Ajinomoto build-up film (ABF), benzocyclo-buthene (BCB), liquid crystal polymer (LCP), poly-imide (PI), poly phenylene ether (PPE), poly tetrafluoro ethylene (PTFE), FR4, FR5, bismaleimide triazine (BT) and aramide.

9. A circuit board assembly with a fine electrically connecting structure, comprising:
a circuit board having a lower surface formed with a first circuit layer and an opposing upper surface formed with second circuit layer, the first circuit layer being formed with a plurality of electric pads corresponding in position to a plurality of formed in the second circuit layer; and a fine electrically connecting structure, made of a conductive composite material with a net-like interconnecting configuration, formed between the corresponding electrical pads, allows the first circuit layer to be electrically connected to the second circuit layer by the means of the fine electrically connecting structure.

10. The circuit board assembly with a fine electrically connecting structure of claim 9, wherein the fine electrically connecting structure, which is made of a conductive composite material, allows copper in the first circuit layer and the second circuit layer to be migrated thereto, so as to electrically connect the first circuit layer and the second circuit layer.

11. The circuit board assembly with a fine electrically connecting structure of claim 10, wherein the copper migration is induced by electricity.

12. The circuit board assembly with a fine electrically connecting structure of claim 10, wherein the conductive composite material is selected from the group consisting of copper (Cu), silver (Ag), graphite, gold (Au), aluminium (Al), magnesium (Mg), iron (Fe) and zinc (Zn).
